(19) United States
(12) Patent Application Publication
(10) Pub. No.: US 2026/0045407 A1
(43) Pub. Date: Feb. 12, 2026

(54) ELECTROMAGNETIC ARRANGEMENT, TRANSFORMER ARRANGEMENT, CHOKE ARRANGEMENT AND CHARGING CONVERTER

(71) Applicant: Siemens Aktiengesellschaft, München (DE)

(72) Inventors: Young Hun Lee, Baldham (DE); Martin Pavlovsky, München (DE); Siegmar Unterweger, München (DE)

(21) Appl. No.: 19/297,178

(22) Filed: Aug. 12, 2025

(30) Foreign Application Priority Data
Aug. 12, 2024 (EP) 24194107.9

(51) Int. Cl. H01F 27/40; H01F 27/28; H01F 27/34; H01F 38/14; H02J 50/12

(52) U.S. Cl. CPC H01F 27/40; H01F 27/34; H01F 38/14; H02J 50/12; H01F 2027/2809; H01F 2027/2819

(57) ABSTRACT

An electromagnetic arrangement configured as an integrated resonant capacitor-inductor-inductor-capacitor arrangement includes a first inductor, a second inductor, a first substrate, a second substrate, a first resonance capacitor, and a second resonance capacitor. The first inductor and the first resonance capacitor are disposed on opposite sides on the first substrate and the second inductor and the second resonance capacitor are disposed on opposite sides on the second substrate. A transformer arrangement, a choke arrangement and a charging converter, each including the electromagnetic arrangement, are also provided.

### CROSS-REFERENCE TO RELATED APPLICATION

This application claims the priority, under 35 U.S.C. § 119, of European Patent Application EP 24194107.9, filed Aug. 12, 2024; the prior application is herewith incorporated by reference in its entirety.

### FIELD AND BACKGROUND OF THE INVENTION

The invention relates to an electromagnetic arrangement, a transformer arrangement, a choke arrangement and a charging converter.

Electromagnetic components or elements are important components in many transformers for a charger, e.g. a DC-DC-charger, or in many common mode chokes for a wireless power transfer system (e.g. WPT compensation boards). Usually, the transformers or common mode chokes are used only to obtain inductance. Needed capacitor boards are provided as separate components.

### SUMMARY OF THE INVENTION

It is accordingly an object of the present invention to provide an improved electromagnetic arrangement, an improved transformer arrangement, an improved choke arrangement and an improved charging converter, e.g. for charging applications, which overcome the hereinafore-mentioned disadvantages of the heretofore-known devices of this general type.

With the foregoing and other objects in view there is provided, in accordance with the invention, an electromagnetic arrangement configured as an integrated resonant capacitor-inductor-inductor-capacitor arrangement, comprising at least a first inductor, a second inductor, a first substrate, a second substrate, a first resonance capacitor, and a second resonance capacitor, wherein the first inductor and the first resonance capacitor are disposed on opposite sides on the first substrate and wherein the second inductor and the second resonance capacitor are disposed on opposite sides on the second substrate. In particular, the electromagnetic arrangement is a hybrid planar electromagnetic arrangement including a planar capacitor-inductor-inductor-capacitor arrangement.

With the objects of the invention in view, there is also provided a transformer arrangement configured as a planar transformer arrangement, comprising the electromagnetic arrangement as defined above.

In an embodiment, the transformer may include potting material. Potting material or an encapsulant, is a type of insulating material used to encapsulate and protect electrical components of the transformer. It can be a liquid resin that hardens to form a solid, protective layer around the components of the transformer.

In an embodiment, the potting material, the first resonance capacitor and the second resonance capacitor are disposed to each other so that the first resonance capacitor and/or the second resonance capacitor can be cooled by the potting material of the transformer.

With the objects of the invention in view, there is furthermore provided a choke arrangement configured as a planar choke arrangement, e.g. a planar common mode choke arrangement, comprising an electromagnetic arrangement as defined above.

With the objects of the invention in view, there is concomitantly provided a charging converter configured as a planar charging converter, comprising the electromagnetic arrangement as defined above.

Preferred embodiments of the invention are given in the dependent claims.

In an embodiment, the first inductor includes one or more primary windings.

In an embodiment, the second inductor includes one or more secondary windings.

In an embodiment, the primary and or secondary windings form a coil.

In an embodiment, the first and/or the second substrate are configured as an integrated circuit board or as integrated circuit boards respectively.

According to examples of the present disclosure, the electromagnetic arrangement is configured as an integrated planar resonant capacitor-inductor-inductor-capacitor arrangement. The electromagnetic arrangement has a very compact size and a low and flat profile configuration and a small size.

The electromagnetic arrangement is produced by using substrates, e.g. PCB material (PCB=printed circuit board). The electromagnetic arrangement improves power density and reduces parasitic capacitance as limiting overlapping area. Further, the electromagnetic arrangement reduces leakage inductance due to tight coupling as inductors are configured as planar windings. The invention allows a simplified and cost-effective production.

According to examples of the present disclosure, the first inductor may be configured as a primary winding, e.g. as at least one of a wire winding, a planar winding printed on a first side of the first substrate and winding tracks printed or etched on the first side of the first substrate, in particular spiral PCB coils with a litz structure (also called PCB litz coils), e.g. a winding wire/coil having a strand including a multiplicity of twisted individual strands. Such a configuration allows a very low profile and small size.

According to examples of the present disclosure, the second inductor may be configured as a secondary winding, e.g. at least one of a wire winding, a planar winding printed on a first side of the second substrate and winding tracks printed or etched on the first side of the second substrate in particular spiral PCB coils with a litz structure (also called PCB litz coils), e.g. a winding wire/coil having a strand including a multiplicity of twisted individual strands. Such a configuration allows a very low profile and small size.

According to examples of the present disclosure, the first inductor is disposed on a single first core disposed on the first side of the first substrate. The first substrate may be configured as a conventional PCB.

According to examples of the present disclosure, the second inductor is disposed on a single second core disposed on the first side of the second substrate. The second substrate may be configured as a conventional PCB.

According to examples of the present disclosure, at least one of the first core and the second core are made from a dielectric material of the substrate. The first core and/or the second core may be made by using the PCB dielectric material itself by interleaving substrate layers. Alternatively, the first core and/or the second core may be configured as a magnetic planar core. In other words, the first core and/or the second core may be configured as a separate or stand-alone component/s or integrated into a multilayer substrate, e.g. a multilayer PCB with slots for ferrite E-core/s.

According to examples of the present disclosure, the first inductor and the second inductor are disposed between the first substrate and the second substrate. In particular, the first inductor and the second inductor are configured as planar windings or planar coils, e.g. spiral PCB coils. Such configuration allows reducing the coupling between the first inductor as planar primary windings and the second inductor as planar secondary windings.

According to examples of the present disclosure, the first resonance capacitor is disposed on a second side of the first substrate. According to examples of the present disclosure, the second resonance capacitor is disposed on a second side of the second substrate. Due to integration of the first resonance capacitor as well as the second resonance capacitor, the size of the electromagnetic arrangement, in particular of a main substrate (also called main PCB), can be reduced and the overall size of the electromagnetic arrangement can be optimized.

According to examples of the present disclosure, a number of connections, e.g. conventional vias, are provided to interconnect ends of the first inductor as primary windings and/or the second inductor as secondary windings, in particular for circuit interconnections. The connections may be configured as conventional vias, e.g. blind vias and/or buried vias.

According to examples of the present disclosure, substrate dielectric layers are provided as insulating barrier between the first inductor and the second inductor. Alternatively, air gaps may be provided between the first inductor and the second inductor.

According to examples of the present disclosure, the electromagnetic arrangement is partially or fully encapsulated with a substrate material, a molding material or an epoxy material for protection.

The invention allows a low and flat profile configuration, low leakage inductance, reduced parasitic properties, an easy production and assembly and includes good thermal characteristics, easy to heatsink due to the planar and integrated capacitor-inductor-inductor-capacitor-configuration. In particular, this capacitor integrated type planar configuration reduces the size of a main PCB and optimizes the whole size of the electromagnetic arrangement. Further, the invention reduces the coupling between the first/primary inductor and the second/secondary inductor. Furthermore, the invention allows an integrated planar capacitive-inductor-inductor-capacitive arrangement with uniform winding arrangements and capacitive arrangements. In particular, the invention allows varying configuration parameters, e.g. winding parameters, winding thickness, core sizes, core layer thickness, layer thickness, airgap, core dimensions, magnetic flux linkage between conductors on primary windings (first inductor) and secondary windings (second inductor), reducing leakage inductances, or combinations thereof.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

Other features which are considered as characteristic for the invention are set forth in the appended claims.

Although the invention is illustrated and described herein as embodied in an electromagnetic arrangement, a transformer arrangement, a choke arrangement and a charging converter, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a diagrammatic, perspective view of an electromagnetic arrangement;

FIG. 2 is a sectional view of the electromagnetic arrangement in an assembled state, which is taken along line II-II of FIG. 1 in the direction of the arrows; and

FIG. 3 is a further sectional view of the electromagnetic arrangement in an assembled state, which is taken along line III-III of FIG. 1 in the direction of the arrows.

### DETAILED DESCRIPTION OF THE INVENTION

Reference will now be made in detail to the present embodiments, examples of which are illustrated in the accompanying drawings. Wherever possible, the same reference numbers will be used throughout the drawings to refer to the same or like parts.

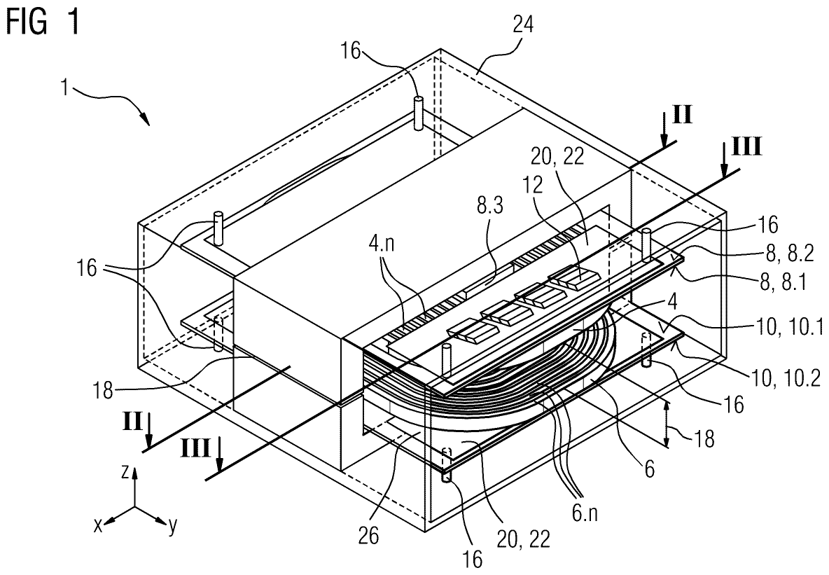

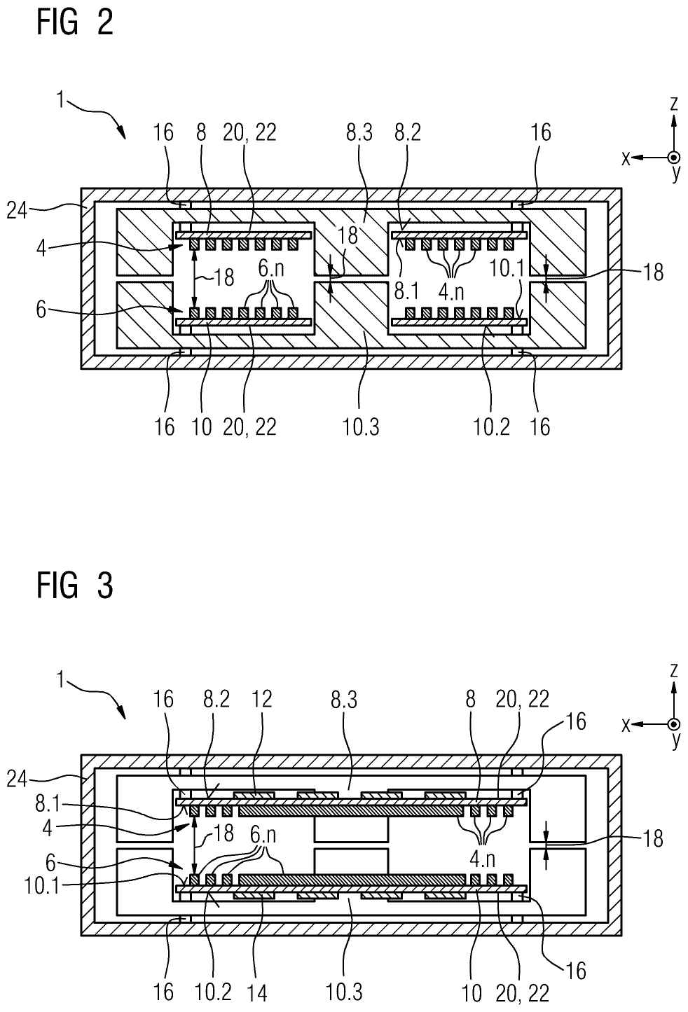

Referring now to the figures of the drawings in detail and first, particularly, to FIG. 1 thereof, there is seen an explanation view of an electromagnetic arrangement 1, e.g. for charging applications. FIG. 2 shows a sectional view of the electromagnetic arrangement 1 in an assembled state according to line II-II in FIG. 1, and FIG. 3 shows a further sectional view of the electromagnetic arrangement 1 in an assembled state according to line III-III in FIG. 1.

The electromagnetic arrangement 1 is configured as an integrated resonant capacitor-inductor-inductor-capacitor arrangement. In particular, the electromagnetic arrangement 1 is a hybrid planar electromagnetic arrangement 1 having a planar resonant capacitor-inductor-inductor-capacitor configuration. The electromagnetic arrangement 1 has a very compact size and a low and flat profile configuration and a small size.

The electromagnetic arrangement 1 includes at least a first inductor 4, a second inductor 6, a first substrate 8, a second substrate 10, a first resonance capacitor 12, and a second resonance capacitor 14.

The first inductor 4 and the first resonance capacitor 12 are disposed on opposite sides 8.1, 8.2 on the first substrate 8. The second inductor 6 and the second resonance capacitor 14 are disposed on opposite sides 10.1, 10.2 of the second substrate 10. The first substrate 8 as well as the second substrate 10 are each configured as an integrated circuit board, e.g. as a conventional PCB (printed circuit board).

The electromagnetic arrangement 1 is produced by using substrates 8, 10, e.g. PCB material. The first inductor 4 may be configured as primary windings 4.n, e.g. as at least one of a wire winding, a planar winding printed on a first side 8.1 of the first substrate 8 and winding tracks printed or etched on the first side 8.1 of the first substrate 8, in particular spiral PCB coils with a litz structure (also referred to as ailed PCB litz coils).

The second inductor 6 may be configured as secondary windings 6.n, e.g. at least one of a wire winding, a planar winding printed on a first side 10.1 of the second substrate 10 and winding tracks printed or etched on the first side 10.1, in particular spiral PCB coils with a litz structure (also called PCB litz coils), e.g. copper conductors with given size, e.g. minimum copper conductor width and/or minimum copper conductor thickness (height), in particular to achieve the required current flow, the power and/or to ensure temperature conditions.

The first inductor 4 is disposed on a single first core 8.3 disposed on the first side 8.1 of the first substrate 8. The second inductor 6 is disposed on a single second core 10.3 disposed on the first side 10.1 of the second substrate 10. For instance, the first inductor 4 and/or the second inductor 6 may be configured as a winding wire/coil having a strand including a multiplicity of twisted individual strands wherein the winding wire/coil is wound around the first core 8.3 and/or the second core 10.3, e.g. four turns, six turns, seven turns (as shown) or a few number of turns.

Alternatively, at least one of the first core 8.3 and the second core 10.3 are partially made from a dielectric material of the substrates 8, 10. The first core 8.3 and/or the second core 10.3 may be made by using the PCB dielectric material itself by interleaving substrate layers. Alternatively, the first core 8.3 and/or the second core 10.3 may be configured as a magnetic planar core/s, e.g. planar ferrite core/s. In other words, the first core 8.3 and/or the second core 10.3 may be configured as a separate or stand-alone component/s or integrated into a multilayer substrate, e.g. a multilayer PCB with slots for ferrite E-core/s.

The first inductor 4 and the second inductor 6 are disposed between the first substrate 8 and the second substrate 10. In particular, the first inductor 4 and the second inductor 6 are configured as planar windings 4.n, 6.n, e.g. planar spiral PCB coils. In particular, the first inductor 4 and the second inductor 6 are disposed opposite each other with a given air gap 18 between them. The first inductor 4 and the second inductor 6 are disposed on the opposite first sides 8.1, 10.1 of the substrates 8, 10. The first sides 8.1, 10.1 are inner sides of the substrates 8, 10.

The first resonance capacitor 12 is disposed on a second side 8.2 of the first substrate 8. The second resonance capacitor 14 is disposed on a second side 10.2 of the second substrate 10. The second sides 8.2, 10.2 are outer sides of the substrates 8, 10.

The primary windings 4.n and the secondary windings 6.n are coupled or connected with the resonance capacitors 12 and 14 with a given resonant frequency, e.g. via connections 16. The connections 16, e.g. conventional vias, are provided to interconnect ends of the first inductor 4 as primary windings 4.n and/or the second inductor 6 as secondary windings 6.n with ends of the first resonance capacitor 12 and/or the second resonance capacitor 14, in particular for circuit interconnections. The connections 16 may be configured as conventional vias, e.g. blind vias and/or buried vias.

Further, the air gaps 18 may be provided between the first inductor 4 and the second inductor 6 and/or the cores 8.3 and 10.3. Alternatively, or additionally, substrate dielectric layers 20 may be provided as an insulating barrier 22.

Furthermore, the electromagnetic arrangement 1 may be partially or fully encapsulated with a housing 24, e.g. an aluminum case. Alternatively, or additionally, the electromagnetic arrangement 1 may be partially or fully encapsulated with a covering material 26, e.g. a substrate material, a molding material or an epoxy material for protection.

The electromagnetic arrangement 1 as defined above may be configured as a planar transformer arrangement or a planar choke arrangement, e.g. a common mode choke, or a planar charging converter.

In an embodiment, the transformer may include potting material. Potting material or an encapsulant, is a type of insulating material used to encapsulate and protect electrical components of the transformer. It can be a liquid resin that hardens to form a solid, protective layer around the components of the transformer.

In an embodiment, the potting material and the capacitors of the electromagnetic arrangement 1 are disposed near to each other so that the capacitors can be cooled by the potting material of the transformer.

1. An electromagnetic arrangement configured as an integrated resonant capacitor-inductor-inductor-capacitor arrangement, the electromagnetic arrangement comprising:
a first inductor;
a second inductor;
a first substrate,
a second substrate;
a first resonance capacitor; and
a second resonance capacitor;
said first inductor and said first resonance capacitor being disposed on opposite sides of said first substrate; and
said second inductor and said second resonance capacitor being disposed on opposite sides of said second substrate.

2. The electromagnetic arrangement according to claim 1, wherein said first inductor is a primary winding configured as at least one of a wire winding, a planar primary winding printed on a first side of said first substrate or winding tracks printed or etched on said first side of said first substrate.

3. The electromagnetic arrangement according to claim 2, wherein said second inductor is a secondary winding configured as at least one of a wire winding, a planar secondary winding printed on a first side of said second substrate or winding tracks printed or etched on said first side of said second substrate.

4. The electromagnetic arrangement according to claim 3, which further comprises a single first core disposed on said first side of said first substrate, said first inductor being disposed on said single first core.

5. The electromagnetic arrangement according to claim 4, which further comprises a single second core disposed on said first side of said second substrate, said second inductor being disposed on said single second core.

6. The electromagnetic arrangement according to claim 4, wherein at least one of said first core or said second core is made of a dielectric material of a corresponding one of said substrates or is made of a magnetic material.

7. The electromagnetic arrangement according to claim 1, wherein said first inductor and said second inductor are disposed between said first substrate and said second substrate.

8. The electromagnetic arrangement according to claim 2, wherein said first resonance capacitor is disposed on a second side of said first substrate.

9. The electromagnetic arrangement according to claim 3, wherein said second resonance capacitor is disposed on a second side of said second substrate.

10. The electromagnetic arrangement according to claim 1, which further comprises a plurality of connections configured to interconnect ends of at least one of said first inductor, said second inductor, said first resonance capacitor or said second resonance capacitor.

11. The electromagnetic arrangement according to claim 1, which further comprises substrate dielectric layers configured as an insulating barrier at least between said first inductor and said second inductor.

12. The electromagnetic arrangement according to claim 1, which further comprises a covering material partially or fully encapsulating the electromagnetic arrangement.

13. A transformer arrangement configured as a planar transformer arrangement, the transformer arrangement comprising the electromagnetic arrangement according to claim 1.

14. A choke arrangement configured as a planar choke arrangement, the choke arrangement comprising the electromagnetic arrangement according to claim 1.

15. A charging converter configured as a planar charging converter, the charging converter comprising the electromagnetic arrangement according to claim 1.
